(19) United States
(12) Patent Application Publication
(10) Pub. No.: US 2012/0015164 A1
(43) Pub. Date: Jan. 19, 2012

(54) Glass product and method for producing the same

(75) Inventors: Kuan-Jiuh Lin, Taichung City (TW); Chuen-Yuan Hsu, Yunlin County (TW)

(73) Assignee: Kuan-Jiuh Lin, Taichung City (TW)

(21) Appl. No.: 13/135,787

(22) Filed: Jul. 14, 2011

(30) Foreign Application Priority Data
Jul. 15, 2010 (TW) 099123268

(51) Int. Cl. B32B 7/02; H01L 31/02; H05H 1/00; B32B 3/26; B32B 15/04

(52) U.S. Cl. 428/213; 428/312.8; 428/336; 428/433; 427/535; 136/252

(57) ABSTRACT

A glass product includes a glass substrate, and a metallic nano-network layer embedded and continuously extending in the glass substrate. A method for producing the glass product is also disclosed.

### CROSS-REFERENCE TO RELATED APPLICATION

This application claims priority of Taiwanese application no. 099123268, filed on Jul. 15, 2010.

### BACKGROUND OF THE INVENTION

1. Field of the Invention

This invention relates to a glass product and a method for producing the same, more particularly to a glass product that is light-transmissive and electrically conductive and that has a metallic nano-network layer, and a method for producing the same.

2. Description of the Related Art

Nanotechnology is currently one of the important technologies, and the development of nanomaterials is the base of nanotechnology. A product made from nanomaterials may have advantages of light-weight, energy-saving, high capacity density, high fineness, high performance, low pollution, etc. The application of nanomaterials may upgrade traditional industries, and promote further development in high-tech industries. Therefore, considerable research efforts in all fields are currently devoted to find out specific properties of nanomaterials.

With the development of nanotechnology, many reports have been published. The inventors of this application have published a research paper, which is entitled “The Facile Fabrication of Tunable Plasmonic Gold Nanostructure Arrays Using Microwave Plasma”, Nanotechnology 21 (2010) 035302 (6 pp). In this paper, there is disclosed a technique for forming arrays of metal nanoparticles on a light-transmissive substrate using microwave plasma. By such technique, the metal nanoparticles, which have a predetermined size and are spaced apart to bond to the light-transmissive substrate, can be formed at a low cost, with high efficiency, using an equipment that is easily available, and through a simple method. With localized surface Plasmon resonance (LSPR) of the metal nanoparticles, the light-transmissive substrate having the metal nanoparticles can be used in a biosensor or other related products. However, there is still a need for developing other nano-related products having other types of nanomaterials, such as fibers, films, etc., in a nano scale.

### SUMMARY OF THE INVENTION

Therefore, an object of the present invention is to provide a glass product and a method for producing the same.

According to the first aspect of this invention, a glass product comprises:

a glass substrate; and

a metallic nano-network layer embedded and continuously extending in the glass substrate.

According to the second aspect of this invention, a method for producing a glass product comprises:

(a) forming at least one noble metal film on a glass substrate;

(b) disposing the glass substrate with the noble metal film into a chamber;

(c) vacuuming the chamber and introducing a plasma-forming gas into the chamber; and

(d) providing a microwave to the chamber to interact with the plasma-forming gas and to produce microwave plasma in the chamber, wherein the noble metal film is melted together with an adjacent portion of the glass substrate to form a metallic nano-network layer embedded and continuously extending in the glass substrate.

According to the third aspect of this invention, a glass product comprises a glass substrate, and a metallic nano-network layer embedded and continuously extending in the glass substrate. The glass product is produced by a method comprising:

(a) forming at least one noble metal film on the glass substrate;

(b) disposing the glass substrate with the noble metal film into a chamber;

(c) vacuuming the chamber and introducing a plasma-forming gas into the chamber; and

(d) providing a microwave to the chamber to interact with the plasma-forming gas and to produce microwave plasma in the chamber, wherein the noble metal film is melted together with an adjacent portion of the glass substrate by the microwave plasma.

### BRIEF DESCRIPTION OF THE DRAWINGS

Other features and advantages of the present invention will become apparent in the following detailed description of the preferred embodiments of the invention, with reference to the accompanying drawings, in which:

FIG. 1 is a flow diagram illustrating a method for producing a glass product according to this invention;

FIG. 2 is a schematic top view showing a metallic nano-network layer in the glass product produced by the method according to this invention;

FIG. 3 is a cross-sectional view of the glass product of FIG. 2;

FIG. 4 is a schematic view illustrating a microwave device used for generating microwave plasma;

FIG. 5 is a block diagram illustrating the preferred embodiment of a method for producing a glass product according to this invention;

FIG. 6(a) illustrates optical properties measured for ten glass substrates before treatment with microwave plasma;

FIG. 6(b) illustrates optical properties for the ten glass substrates after treatment with the microwave plasma;

FIG. 7 (a)˜7(f) illustrate scanning electron microscope images for the metallic nano-network layers that are respectively made of metal films having different thicknesses;

FIG. 8 (a) is a scanning electron microscope image of a metal film before being treated by the microwave plasma;

FIG. 8 (b) is a scanning electron microscope image of a metallic nano-network layer formed from the metal film after being treated by the microwave plasma;

FIG. 9 is a diagram illustrating plots of electrical resistance as a function of temperature;

FIG. 10(a) illustrates optical properties for six glass substrates, each of which has an Ag film and an Au film with predetermined thicknesses and is not treated by microwave plasma;

FIG. 10(b) illustrates optical properties for the six glass substrates, each of which has a metallic nano-network layer made of the Ag/Au films using the microwave plasma; and

FIGS. 11(a) and 11(b) are two scanning electron microscope images for two metallic nano-network layers that are respectively made of Ag/Au films with different thicknesses.

### DETAILED DESCRIPTION OF THE PREFERRED EMBODIMENTS

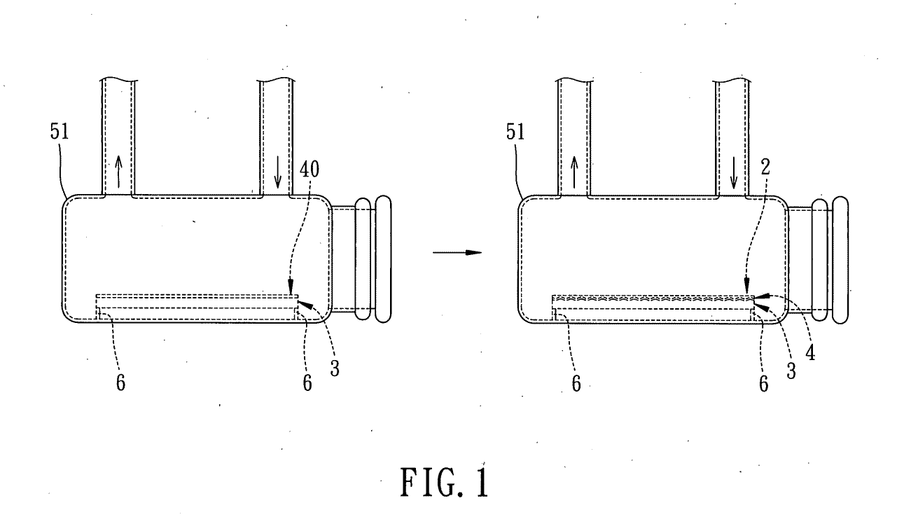

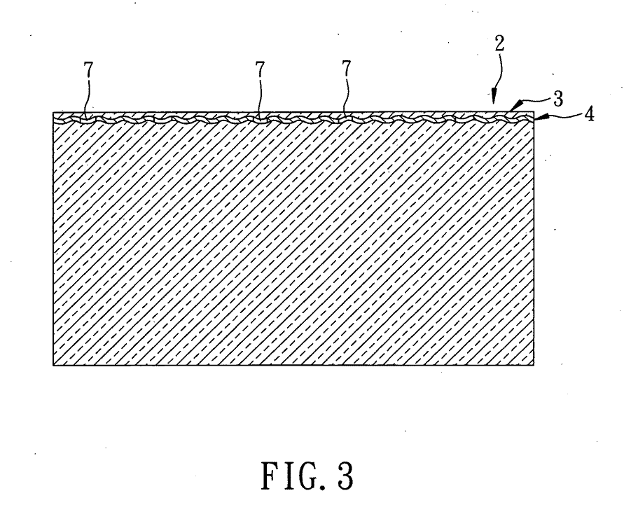

Referring to FIGS. 1 to 3, the preferred embodiment of a glass product 2 according to this invention includes a glass substrate 3, and a metallic nano-network layer embedded and continuously extending in the glass substrate 3.

The glass substrate 3 is made of a light-transmissive material.

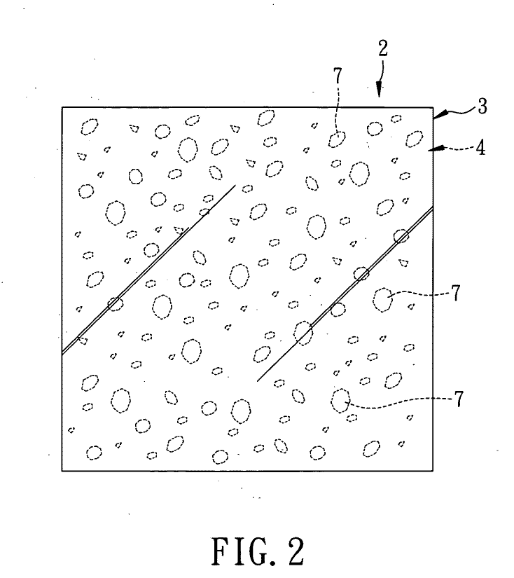

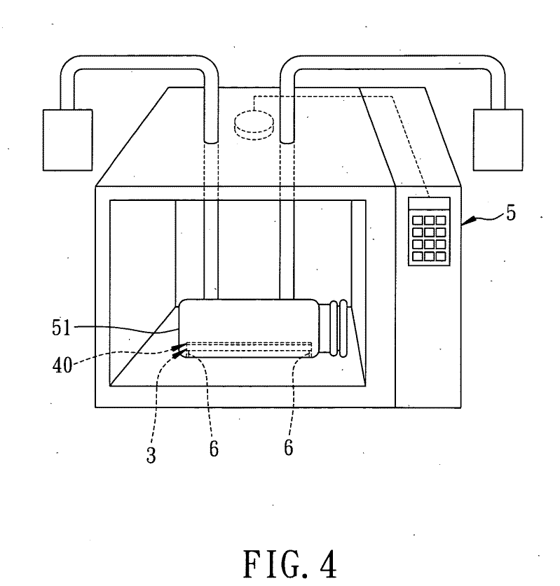

The metallic nano-network layer 4 includes a plurality of spaced apart pores 7 (see FIG. 2), and is made of a noble metal film 40 that is formed on the glass substrate 3. The noble metal film 40 is treated using microwave plasma for a period of time to form the metallic nano-network layer 4. The noble metal film 40 includes a material selected from Au and Ag. When the noble metal film 40 that includes only one material is formed on the glass substrate 3, the metallic nano-network layer 4 is a single metallic layer. When two noble metal films 40 that are made respectively from two different metals are deposited on the glass substrate 3, the metallic nano-network layer 4 is an alloy layer. The alloy layer is formed by forming two noble metal films 40 (for example, an Au film and an Ag film) on the glass substrate 3, followed by treating the two noble metal films 40 (only one is shown in FIGS. 1 and 4) using microwave plasma.

Because the noble metal film 40 has a thickness in a nano-scale, it can be controlled to permit passage of visible light and to block and reflect infrared ray. Accordingly, the thickness of the noble metal film 40 is preferably from about 7 nm to about 18 nm, and more preferably from about 8 nm to about 11 nm. After the noble metal film 40 is treated by the microwave plasma to form the metallic nano-network layer 4, the transmittance of the visible light can be increased through the network structure of the metallic nano-network layer 4, but the reflectivity with respect to the infrared ray is substantially not affected. Furthermore, since the metallic nano-network layer 4 is embedded in the glass substrate 3, the metallic nano-network layer 4 can be protected from oxidizing and from peeling to prolong a service life of the glass product 2.

Since the metallic nano-network layer 4 permits passage of the visible light, can block the infrared ray, and is electrically conductive, the glass product 2 may be applied to an energy-saving glass, a touch panel, a solar cell, an antistatic glass, a frosting-resistant glass, an anti-electromagnetic wave glass, or an electrochromic glass. For example, when the glass product 2 is used in an energy-saving glass for a room, it prevents the infrared energy from entering the room, thus saving the energy for cooling the room. When the glass product 2 is used in a frosting-resistant glass, the frost on the glass product 2 can be removed by applying electricity to the metallic nano-network layer 4 to increase a temperature of the glass substrate 3. When the glass product 2 serves as an anti-electromagnetic wave glass, the metallic nano-network layer 4 made of a metal material can block the electromagnetic wave. When the glass product 2 serves as an antistatic glass, a static electricity generated due to rubbing can be released through the metallic nano-network layer 4. When the glass product 2 is used for making an electrochromic glass, an electrochromic layer may be formed on a surface of the glass substrate 3 close to the metallic nano-network layer 4. The electrochromic layer may be made of silica, and can have different colors corresponding to different oxidation states. The oxidation state of the silicon dioxide may be controlled and varied by a current direction applied to the metallic nano-network layer 4. Besides, because a temperature of a solar cell increases with the sun exposure time, it is likely to experience thermal agitation inside crystal lattices of the solar cell. Thus, power generation efficiency of the solar cell may be reduced. By combining the glass product 2 with the solar cell, the infrared ray can be efficiently blocked by the metallic nano-network layer 4 to alleviate the thermal agitation. Furthermore, the metallic nano-network layer 4 has a surface resistance of about 14 Ω/sq that is close to a surface resistance of a transparent conductive glass, and thus, the glass product 2 also has a potential to serve as a transparent conductive glass of a touch panel.

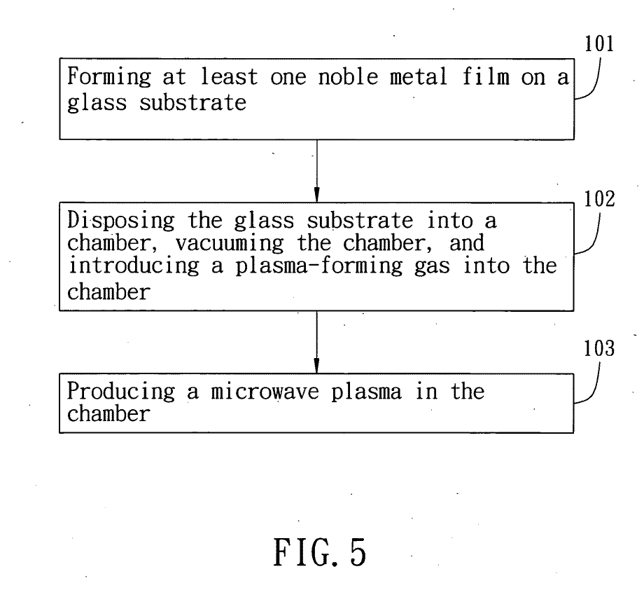

Referring to FIGS. 1, 4, and 5, a method for producing the glass product 2 comprises the following steps.

In step 101, at least one noble metal film 40 is formed on the glass substrate 3. Preferably, the noble metal film 40 is formed by sputter coating, and the thickness of the noble metal film 40 is controlled by a film thickness measurement instrument (FTM). The technique for sputter coating is well-known in the relevant art, and a detailed description thereof is omitted herein for the sake of brevity.

In step 102, the glass substrate 3 with the noble metal film 40 is disposed into a chamber 51 of a microwave device 5. Then, the chamber 51 is vacuumed, and a plasma-forming gas is introduced into the chamber 51 so that a pressure inside the chamber 51 is controlled at about 0.05 torr to about 0.5 torr. The plasma-forming gas may be argon, nitrogen, or oxygen. When the pressure inside the chamber 51 is greater than 0.5 torr, microwave plasma resulting therefrom will have a relatively low energy or temperature that cannot provide heat sufficient to form the glass substrate 3 and the noble metal film 40 into the glass product 2. When the pressure inside the chamber 51 is lower than 0.05 torr, it is hard to generate the microwave plasma by excitation. Preferably, a plurality of spaced apart supports 6 are provided under the glass substrate 3. Thus, the glass substrate 3 has a portion in contact with the supports in the chamber 51 and a remaining portion being suspended.

In step 103, a microwave is provided to the chamber 51 for a predetermined period of time to interact with the plasma-forming gas so that the microwave plasma is produced in the chamber 51. With the energy of the microwave plasma, the noble metal film 40 is melted together with a portion of the glass substrate 3 adjacent to the noble metal film 40 to form a metallic nano-network layer 4 embedded and continuously extending in the glass substrate 3. In detail, when the noble metal film 40 is melted, it aggregates due to its surface tension resulting in a plurality of spaced apart pores in the noble metal film 40. However, because the thickness of the noble metal film 40 is not less than 7 nm, the noble metal film 4 forms a continuous network structure of the metallic nano-network layer 4. Besides, because the noble metal film 40 has a relatively high temperature when treated by the microwave plasma, the portion of the glass substrate 3 adjacent to the noble metal film 40 is also melted. Since the noble metal in the metallic nano-network layer 4 has a specific gravity greater than that of the glass substrate 3, the metallic nano-network layer 4 sinks in the melt of the glass substrate 3. Accordingly, the metallic nano-network layer 4 is an embedded network layer in the glass product 2.

It is worthwhile to mention that, in step 102, by supporting the glass substrate 3 using the supports 6, except parts of the glass substrate 3 that are in contact with the supports 6, most parts of the glass substrate 3 are suspended. Therefore, the phenomenon that the energy of the microwave plasma applied to the noble metal film 40 is undesirably absorbed by the chamber 51 through the glass substrate 3 can be alleviated. Therefore, by the provision of the supports 6, the microwave plasma can be efficiently applied on the noble metal film 40.

### Experiment 1

### Preparation of Glass Products Each Including a Metallic Nano-Network Layer Made of Au

(1) Preparation of Glass Substrates

Ten glass substrates, each having a size of 1 cm×1 cm, were prepared. In order to remove contaminating particles adhered to the glass substrates, each glass substrate was ultrasonic treated in acetone for 5 minutes, in ethanol for 5 minutes, and in deionized water for 5 minutes, sequentially, followed by drying using nitrogen gas. Then, the glass substrates were soaked in piranha solution (a 3:1 mixture of concentrated H₂SO₄ and 30% H₂O₂) for 30 minutes at 80° C. to remove organic residues on the glass substrates, rinsed in a large volume of deionized water, and fully dried using the nitrogen gas.

Each glass substrate that had been cleaned was disposed in a sputter coater to coat with an Au film. The ten glass substrates were respectively labeled using the alphanumeric codes A1, B1, C1, D1, E1, F1, G1, H1, I1, and J1, and the thicknesses of the Au films on the ten glass substrates A1, B1, C1, D1, E1, F1, G1, H1, I1, and J1 were 6 nm, 8 nm, 9 nm, 10 nm, 10.5 nm, 11 nm, 12 nm, 13 nm, 14 nm, and 18 nm, respectively.

(2) Microwave Plasma Treatment of the Glass Substrates

Each glass substrate was disposed in a chamber of a microwave device that has a microwave emitting unit. A pressure inside the chamber was maintained at 0.25 torr by vacuuming the chamber using a vacuum pump, and by introducing argon gas into the chamber. Thereafter, the microwave emitting unit was controlled to emit 2.45 GHz for 120 seconds to interact with the argon gas and to produce microwave plasma in the chamber. After the microwave plasma traveled to the Au film on the glass substrate, the Au film was melted together with a portion of the glass substrate adjacent to the Au film to form a metallic nano-network layer embedded and continuously extending in the glass substrate. Accordingly, ten glass products were produced.

(3) Measurements of Optical and Electrical Properties for the Glass Products Before and after the Microwave Plasma Treatment

Test samples for measuring optical and electrical properties include the ten glass substrate each being formed with the Au film, and the ten glass products each including the metallic nano-network layer.

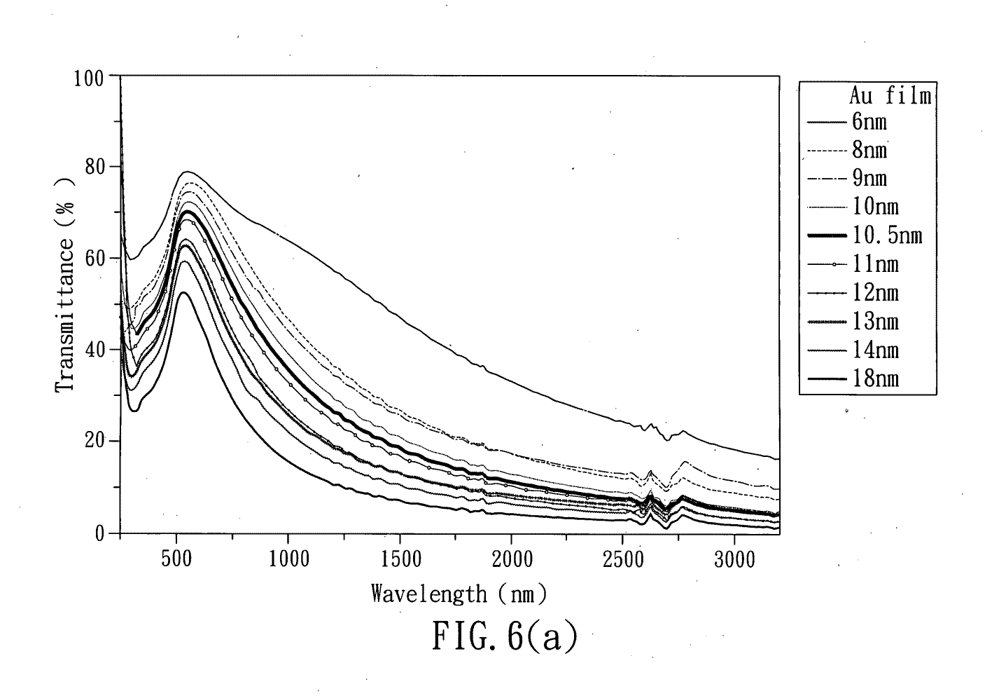

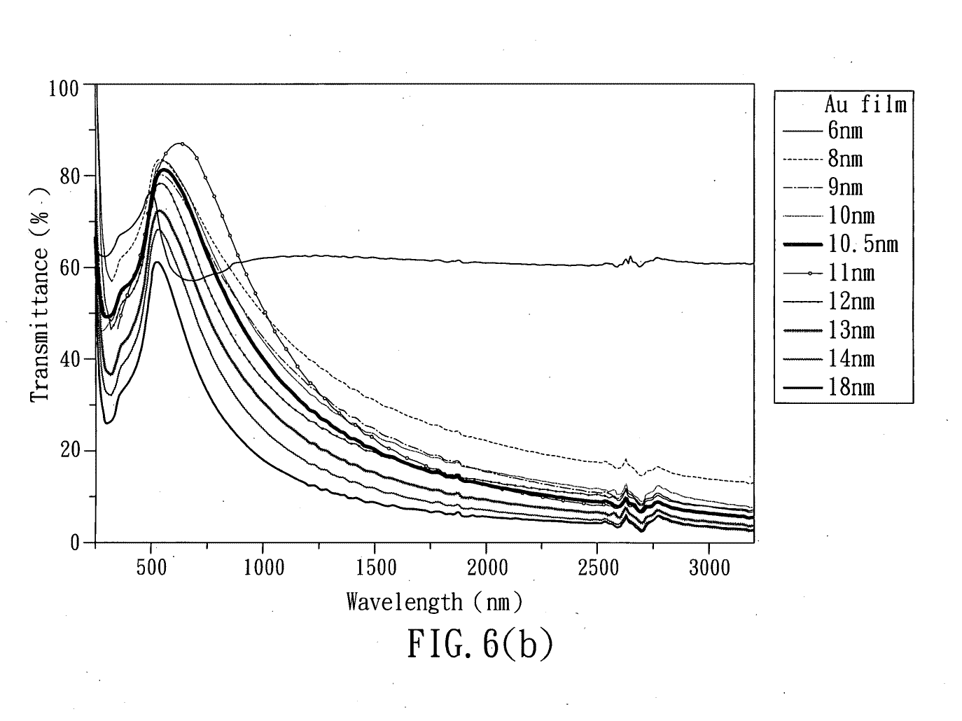

Transmittances of the test samples were measured for a wavelength range that includes a visible light region and an infrared region and were plotted as a function of wavelength. FIG. 6(a) illustrates the plots obtained for the ten glass substrates each having the Au film. FIG. 6(b) illustrates the plots obtained for the ten glass products. Transmittances at the wavelengths of 550 nm and 3200 nm for each test sample are shown in Table 1.

The electrical property for each of the ten glass products was measured by (1) selecting a reference point on a measuring surface of each glass product that is adjacent to the metallic nano-network layer, (2) selecting three spaced apart measuring points on the measuring surface, and (3) measuring electrical resistances at the three measuring points relative to the reference point. When measuring the electrical resistance between the reference point and one of the three measuring points, two testing probes were respectively pierced into the reference point and the corresponding measuring point on the glass substrate to make contact with the metallic nano-network layer, and then the electrical resistance between the two testing probes was measured. The electrical property results are shown in Table 2.

TABLE 1
Comparison of Optical Properties Before and
After The Microwave Plasma Treatment

| Code | | Transmittance | | Transmittance | |
|---|---|---|---|---|---|
| (thickness | | at 550 nm (%) | | at 3200 nm (%) | |
| of the Au | | Before | After | Before | After |
| film) | | treating | treating | treating | treating |
| A1 | (6 nm) | 79 | 65 | 16 | 60 |
| B1 | (8 nm) | 76 | 83 | 10 | 13 |
| C1 | (9 nm) | 74 | 80 | 8 | 7 |
| D1 | (10 nm) | 72 | 83 | 5 | 8 |
| E1 | (10.5 nm) | 70 | 81 | 4 | 5 |
| F1 | (11 nm) | 68 | 84 | 4 | 5 |
| G1 | (12 nm) | 63 | 78 | 4 | 7 |
| H1 | (13 nm) | 62 | 72 | 3 | 4 |
| I1 | (14 nm) | 59 | 67 | 3 | 3 |
| J1 | (18 nm) | 52 | 60 | 1 | 3 |

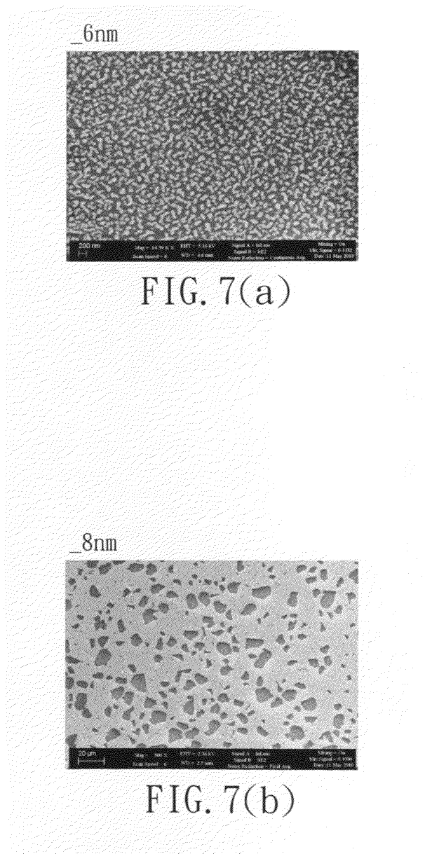

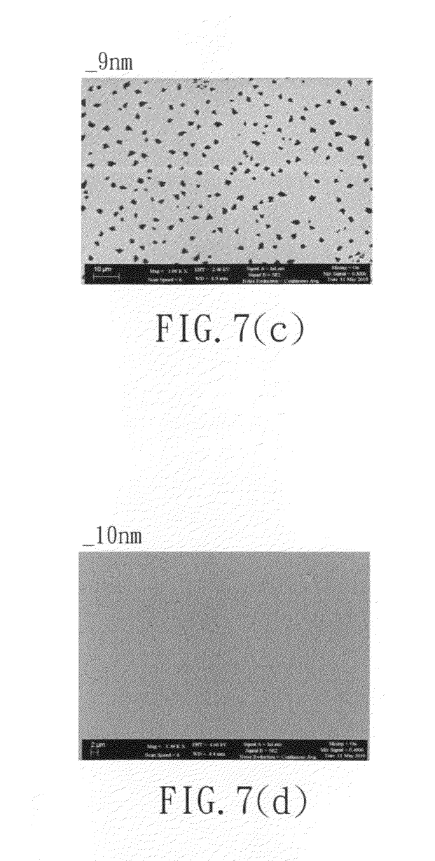

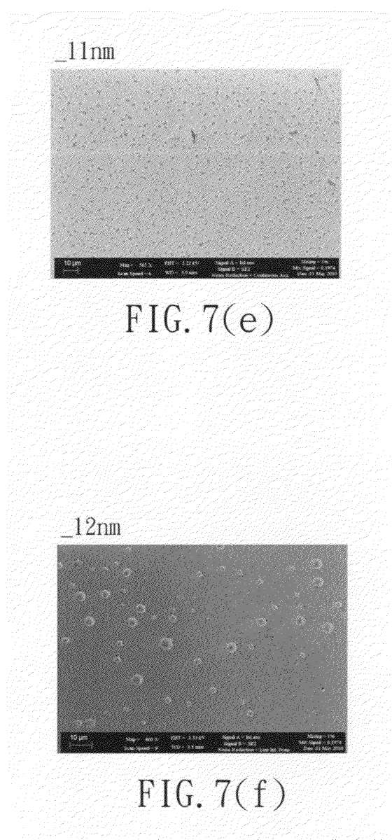

As shown in Table 1, the Au films of A1-J1, before the microwave plasma treatment, are thin, and have relatively large transmittance for the visible light (550 nm), and relatively low transmittance for the infrared ray (3200 nm). Thus, the Au films may be used for blocking the infrared ray. The transmittances for the visible light and the infrared ray decrease as the thickness of the Au film increases. After the microwave plasma treatment, the transmittances for the visible light of the glass products (except A1) are improved. However, the reflecting/blocking abilities of the glass products (except A1) for the infrared ray are not significantly affected. As shown in FIG. 7(a), in the case of A1, the nanoparticles of the Au film are separated individually and do not form the continuous network structure of metallic nano-network layer after the microwave plasma treatment. It is speculated that degradation of the optical properties in A1 after treatment is due to the very thin film of A1. After the microwave plasma treatment, the glass product of A1 has the transmittance of 60% for the infrared ray, and cannot block the infrared ray efficiently. Furthermore, it is noted that, although the Au films formed on the glass substrates before the microwave plasma treatment also permit passage of the visible light and block the infrared ray, because the Au films are exposed from the glass substrates, they are susceptible to damage and losses in optical properties thereof. With the microwave plasma treatment, the Au film was formed into the metallic nano-network layer embedded in the glass substrate, and the metallic nano-network layer can also provide the same or better optical properties of the Au films. Since the metallic nano-network layer is embedded in the glass substrate, it can be protected from oxidizing or peeling, and has a relatively long service life.

Besides, it is noted that, from the results of Table 1, the thickness of the Au film is preferably from about 7 nm to about 18 nm, and more preferably from about 8 nm to about 11 nm. This is because when the thickness of the Au film ranges from 8 nm to 11 nm, the transmittance of the glass product for the visible light is higher than 80% while still maintaining its good reflectivity for the infrared ray. Furthermore, when the thickness of the Au film increases from 14 nm (I1) to 18 nm (J1), the transmittance for the infrared ray is nearly minimum, and the reflectivity is nearly maximum (i.e. the transmittance is 1 or 3% and the reflectivity is 99 or 97%). Therefore, even when the thickness of the Au film is increased, the reflectivity cannot be increased further. Because the increase in thickness will increase costs, the thickness of the metal film is preferably smaller than 18 nm.

TABLE 2
Comparison of Electrical Properties Before and
After the Microwave Plasma Treatment

| Code | | Resistance | | | | |
|---|---|---|---|---|---|---|
| (thickness | | before | | | | |
| of the Au | | treating | Resistance after treating (Ω) | | | |
| film) | | (Ω) | Point 1 | Point 2 | Point 3 | Avg. |
| A1 | (6 nm) | 57 | ∞ | ∞ | ∞ | ∞ |
| B1 | (8 nm) | 37 | 17 | 16 | 18 | 17 |
| C1 | (9 nm) | 28 | 12 | 9 | 11 | 10 |
| D1 | (10 nm) | 26 | 11 | 10 | 11 | 11 |
| E1 | (10.5 nm) | 26 | 10 | 9 | 10 | 10 |
| F1 | (11 nm) | 24 | 11 | 10 | 11 | 11 |
| G1 | (12 nm) | 22 | 9 | 8 | 9 | 9 |
| H1 | (13 nm) | 21 | 12 | 10 | 9 | 10 |
| I1 | (14 nm) | 18 | 9 | 8 | 9 | 9 |
| J1 | (18 nm) | 16 | 8 | 7 | 7 | 7 |

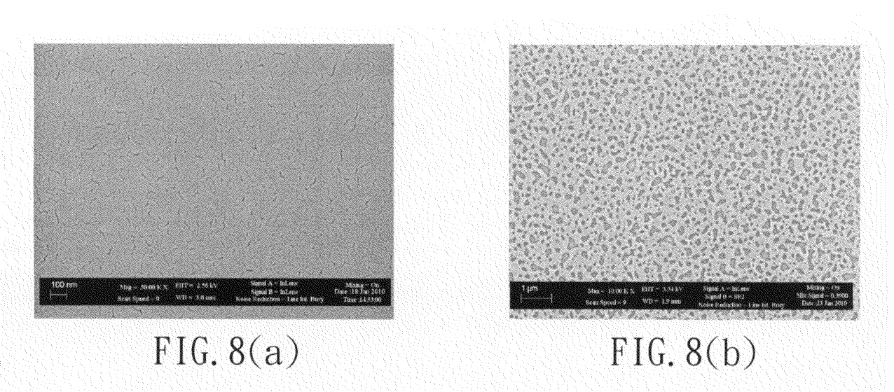

From the results of Table 2, it is noted that after the microwave plasma treatment, the electrical resistances of the glass products (except A1) are reduced. The results indicate that, except A1, the glass products have excellent electrical conductivity after the microwave plasma treatment. A main reason for the high electrical resistance before the microwave plasma treatment is that the very thin Au film of each of the glass products formed by a depositing method, such as sputtering before the microwave plasma treatment is liable to have fissures (see FIG. 8(a)), which result in discontinuity of the Au film and hence poor electrical conduction. However, after the microwave plasma treatment, the Au film is formed into the continuous network structure of the metallic nano-network layer, and no fissure appears in all areas of the metallic nano-network layer other than pore-forming sites of the metallic nano-network layer (see FIG. 8(b)). Accordingly, the electron transportation in the metallic nano-network layer of the glass product is improved, and the electrical resistance is reduced. Therefore, from the results of Table 2, the thickness of the Au film is preferably about 7 nm to about 18 nm. Regarding sample A1, because the Au film that is merely 6 nm thick is formed into individual nanoparticles, when it was tested, a very high electrical resistance (substantially as high as that of an insulator) was measured.

The scanning electron microscope images of the metallic nano-network layers in the glass products of A1, B1, C1, D1, F1, and G1 are shown in FIGS. 7(a)˜7(f). As mentioned above, in the glass product of A1, the metallic nano-network layer was not formed (see FIG. 7(a)), and thus, the glass product of A1 cannot efficiently block the infrared ray and the electrical resistance is relatively large. Referring to FIGS. 7(b) to 7(f), the amount and size of the pores in the metallic nano-network layers of the glass products decrease with an increase in thickness of the Au film.

(4) Thermal Test

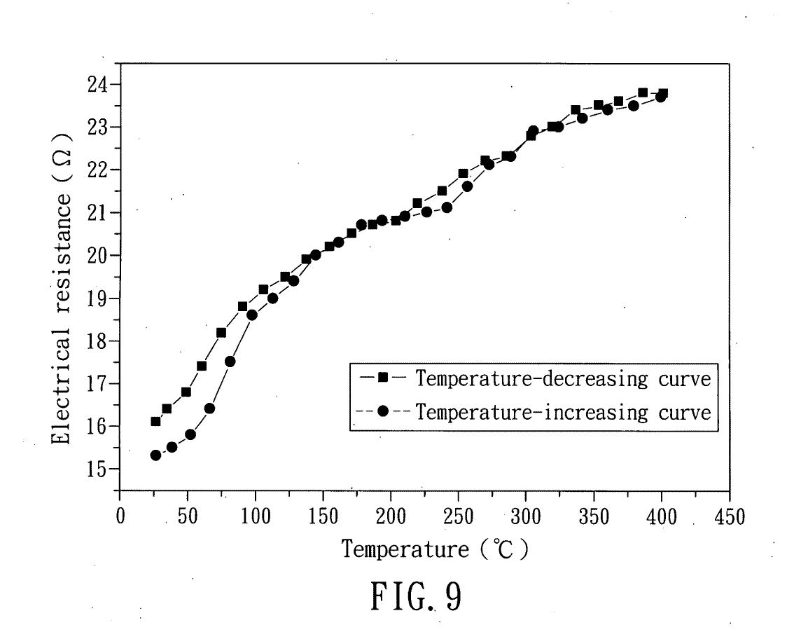

The glass product of F1 was disposed in a heating chamber, and was pierced by two testing probes that extended through the metallic nano-network layer to contact the same at two points for measurement of an electrical resistance between the two points. FIG. 9 shows a temperature-increasing curve obtained by measuring the electrical resistance when the temperature of the glass product is increased from room temperature to 400° C., and a temperature-decreasing curve obtained by measuring the electrical resistance when the temperature of the glass product is decreased from 400° C. to room temperature. As the temperature increases, the thermal agitation inside the metallic nano-network layer increases, resulting in an increase in the electrical resistance. When the temperature decreases, the electrical resistance also decreases. The temperature-increasing curve is very close to the temperature-decreasing curve. Presumably, the structure of the metallic nano-network layer, which is protected by the glass substrate, is stable and is not oxidized or damaged when the temperature is increased.

However, when the Au film on the glass substrate that was not treated with the microwave plasma was subjected to the same thermal test, it was found that, even when the thickness was increased to 100 nm, the Au film was damaged and became discontinuous when the temperature was increased to 200° C. In addition, after the temperature was decreased back to room temperature, the Au film did not return to its conductive state.

### Experiment 2

### Preparation of Glass Products Each Including a Metallic Nano-Network Layer Made of Au and Ag

By following the procedures employed in experiment 1, six glass substrates were prepared in this experiment. However, two noble metal films that were made respectively from two different metals (i.e., an Ag film and an Au film) were formed on each of the glass substrates, and the microwave emitting unit was controlled to emit 2.45 GHz microwave for 90 seconds. Each of the glass substrates was coated with the Ag film, followed by coating with the Au film to fully cover the Ag film on the glass substrate. Therefore, Ag film is disposed below the Au film and is protected by the Au film. The reason for forming the Ag film below the Au film is that the Ag film is likely to evaporate during the microwave plasma treatment, and the evaporation can adversely affect the formation of the metallic nano-network layer. The six substrates were respectively labeled using the alphanumeric codes A2, B2, C2, D2, E2, and F2, and the thickness of Ag/Au films on the glass substrates A2, B2, C2, D2, E2, and F2 were 2 nm Ag/9 nm Au, 2 nm Ag/10 nm Au, 2 nm Ag/11 nm Au, 4 nm Ag/9 nm Au, 4 nm Ag/10 nm Au, and 4 nm Ag/11 nm Au, respectively.

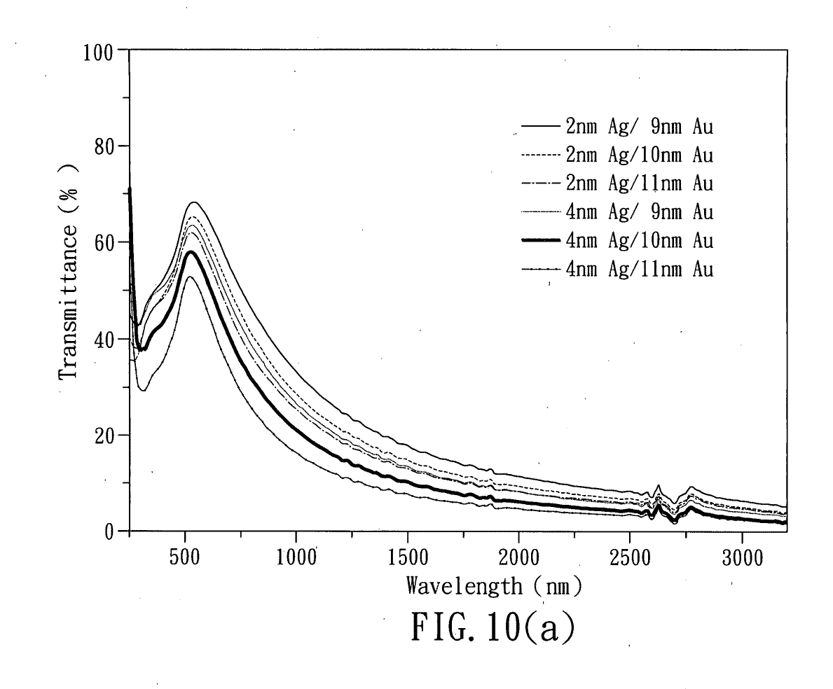

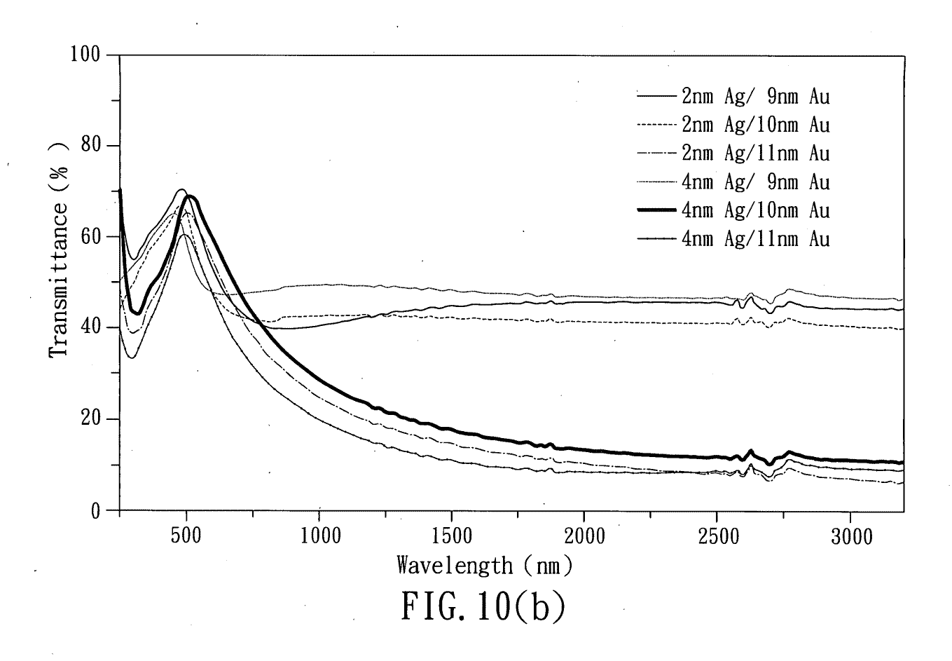

FIG. 10(a) illustrates optical properties for the six glass substrates each having the Ag/Au films, and FIG. 10(b) illustrates optical properties for the six glass products. The transmittances at wavelengths of 550 nm and 3200 nm for the glass substrates and the glass products are listed in Table 3. The electrical resistances for the glass substrates and the glass products are listed in Table 4.

TABLE 3
Comparison of Optical Properties Before and
After The Microwave Plasma Treatment

| Code | | Transmittance | | Transmittance | |
|---|---|---|---|---|---|
| (thickness of | | at 550 nm (%) | | at 3200 nm (%) | |
| the Ag/Au | | Before | After | Before | After |
| films) | | treating | treating | treating | treating |
| A2 | (2 nm/9 nm) | 68 | 60 | 5 | 44 |
| B2 | (2 nm/10 nm) | 64 | 55 | 4 | 40 |
| C2 | (2 nm/11 nm) | 61 | 61 | 4 | 7 |
| D2 | (4 nm/9 nm) | 62 | 50 | 3 | 47 |
| E2 | (4 nm/10 nm) | 57 | 66 | 2 | 11 |
| F2 | (4 nm/11 nm) | 51 | 54 | 1 | 9 |

In view of the results in Table 3, although the microwave plasma treatment cannot improve the blocking effect of the glass products for the infrared ray, the transmittance of the glass products (E2 and F2) for the visible light (E2 and F2) can be improved when the thickness of the Ag film is 4 nm, and the thickness of the Au film is not less than 10 nm.

TABLE 4
Comparison of electrical properties before and
after the microwave plasma treatment

| Code | | Resistance | | | | |
|---|---|---|---|---|---|---|
| (thickness of | | before | | | | |
| the Ag/Au | | treating | Resistance after treating (Ω) | | | |
| films) | | (Ω) | Point 1 | Point 2 | Point 3 | Avg. |
| A2 | (2 nm/9 nm) | 25 | ∞ | ∞ | ∞ | ∞ |
| B2 | (2 nm/10 nm) | 18 | ∞ | 665 | ∞ | ∞ |
| C2 | (2 nm/11 nm) | 15 | 40 | 33 | 42 | 38 |
| D2 | (4 nm/9 nm) | 20 | ∞ | ∞ | ∞ | ∞ |
| E2 | (4 nm/10 nm) | 18 | 32 | 27 | 25 | 28 |
| F2 | (4 nm/11 nm) | 15 | 26 | 21 | 27 | 25 |

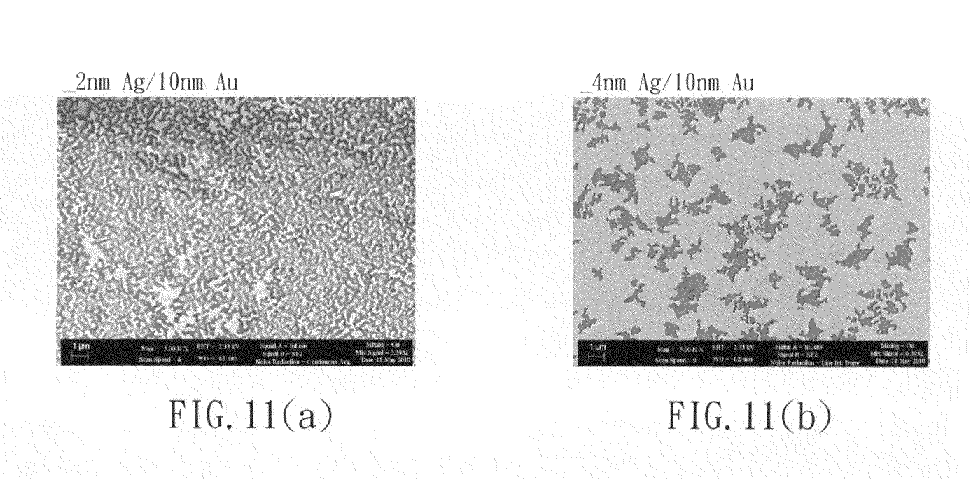

The results of Table 4 show that, although the microwave plasma treatment cannot reduce the electrical resistances, the electrical resistances of the metallic nano-network layers in the glass products (E2 and F2) are still acceptable. FIG. 11(a) shows a plurality of irregular individually separated particles in the glass product of B2. The electrical resistance measured from the glass product of B2 is extremely large as shown in Table 4. FIG. 11(b) shows that the continuous network structure of the metallic nano-network layer was formed in the glass product of E2. The electrical resistance measured from the glass product of E2 is relatively low as shown Table 4.

While the present invention has been described in connection with what are considered the most practical and preferred embodiments, it is understood that this invention is not limited to the disclosed embodiments but is intended to cover various arrangements included within the spirit and scope of the broadest interpretations and equivalent arrangements.

What is claimed is:

1. A glass product, comprising:
a glass substrate; and
a metallic nano-network layer embedded and continuously extending in said glass substrate.

2. The glass product of claim 1, wherein said metallic nano-network layer includes a plurality of spaced apart pores, and is made of a metal film that is formed in said glass substrate and that has a thickness of about 7 nm to about 18 nm.

3. The glass product of claim 2, wherein said thickness of said metal film ranges from about 8 nm to about 11 nm.

4. The glass product of claim 2, wherein said metal film includes a material selected from Au and Ag.

5. The glass product of claim 1, wherein said metallic nano-network layer includes two metal films that are made respectively from two different metals and that have a total thickness of about 7 nm to about 18 nm.

6. The glass product of claim 5, wherein one of said metal films is an Au film, and the other one of said metal films is an Ag film.

7. The glass product of claim 6, wherein said Au film is disposed on said Ag film.

8. The glass product of claim 7, wherein said Au film has a thickness not less than about 10 nm.

9. The glass product of claim 2, which is a product selected from the group consisting of an energy-saving glass, a touch panel, a solar cell, an antistatic glass, a frosting-resistant glass, an anti-electromagnetic wave glass, and an electrochromic glass.

10. A method for producing a glass product, comprising:
(a) forming at least one noble metal film on a glass substrate;
(b) disposing the glass substrate with the noble metal film into a chamber;
(c) vacuuming the chamber and introducing a plasma-forming gas into the chamber; and
(d) providing a microwave to the chamber to interact with the plasma-forming gas and to produce microwave plasma in the chamber, wherein the noble metal film is melted together with an adjacent portion of the glass substrate to form a metallic nano-network layer embedded and continuously extending in the glass substrate.

11. The method of claim 10, wherein the noble metal film has a thickness ranging from about 7 nm to about 18 nm.

12. The method of claim 11, wherein the thickness of the noble metal film ranges from about 8 nm to about 11 nm.

13. The method of claim 11, wherein the noble metal film is made of a material selected from Au and Ag.

14. The method of claim 11, wherein, in the step (a), two noble metal films are formed, one of which is an Au film, the other of which is an Ag film.

15. The method of claim 14, wherein, in the step (a), the Ag film is formed on the glass substrate, and the Au film is formed on the Ag film.

16. The method of claim 15, wherein the Au film has a thickness not less than about 10 nm.

17. The method of claim 11, further comprising a step of providing at least one support under the glass substrate, the glass substrate having a portion in contact with the support in the chamber and a remaining portion being suspended.

18. The method of claim 10, wherein a pressure inside the chamber is controlled at about 0.05 torr to about 0.5 torr.
